(19) United States
(12) Patent Application Publication
(10) Pub. No.: US 2026/0092999 A1
(43) Pub. Date: Apr. 2, 2026

(54) Acquiring Diffusion-Weighted Measurement Data Using Non-Trapezoidal Gradient Pulse Shapes for the Diffusion Encoding

(71) Applicant: Siemens Healthineers AG, Forchheim (DE)

(72) Inventor: Thorsten Feiweier, Poxdorf (DE)

(73) Assignee: Siemens Healthineers AG, Forchheim (DE)

(21) Appl. No.: 19/340,997

(22) Filed: Sep. 26, 2025

(30) Foreign Application Priority Data
Sep. 30, 2024 (DE) 10 2024 209 539.7

(51) Int. Cl. G01R 33/563; G01R 33/56

(52) U.S. Cl. CPC G01R 33/56341; G01R 33/5602; G01R 33/5608

(57) ABSTRACT

The disclosure is directed to a method and system for acquiring diffusion-weighted measurement data using a magnetic resonance system with non-trapezoidal gradient pulse shapes. The method may include: a) loading prepared characteristics for at least one non-trapezoidal gradient pulse shape of the measurement protocol; b) loading limit values that the magnetic resonance system's hardware must not exceed; c) assigning possible parameter values of measurement parameters to categories indicating executability of the measurement protocol based on the loaded characteristics while complying with the limit values; d) inputting desired parameter values for measurement parameters while considering the assignment; e) if executable parameter values have not been input for every measurement parameter, repeating steps c) and d) until executable parameter values are input for all measurement parameters to be set; and f) acquiring diffusion-weighted measurement data using the measurement protocol containing the input parameter values.

### CROSS REFERENCE TO RELATED APPLICATIONS

This patent application claims priority to German Patent Application No. 102024209539.7, filed Sep. 30, 2024, which is incorporated herein by reference in its entirety.

### BACKGROUND

The disclosure relates to an improvement in the acquisition of diffusion-weighted measurement data using non-trapezoidal gradient pulse shapes for the diffusion encoding, such as while considering limit values specified by a hardware unit of a magnetic resonance system used.

Magnetic resonance (MR) technology is a well-known modality by means of which images of the interior of an examination subject can be generated. In simple terms, the examination subject is positioned for this purpose in a magnetic resonance apparatus in a comparatively strong, static, homogeneous basic magnetic field, also referred to as the B0 field, at field strengths of 0.2 Tesla to 7 Tesla and more such that the nuclear spins thereof align themselves along the basic magnetic field. In order to trigger nuclear spin resonances that are measurable as signals, radiofrequency excitation pulses (RF pulses) are radiated into the examination subject, the triggered nuclear spin resonances are measured as values known as k-space data by means of coils configured for receiving signals, and MR images are reconstructed or spectroscopic data is determined on the basis thereof. The alternating magnetic field generated by the excitation pulses radiated in by means of at least one transmit coil is also referred to as the B1 field. In order to spatially encode the measurement data, rapidly switched magnetic gradient fields, called gradients for short, are superimposed on the basic magnetic field. A variation with time of such a gradient field, for example, in the direction of a gradient axis, may also be referred to as a gradient pulse shape. A scheme used that describes a temporal sequence of RF pulses to be transmitted and gradients to be switched is referred to as a pulse sequence (scheme), or also as a sequence for short. The recorded measurement data is digitized and stored in the form of complex numeric values in a k-space matrix. An associated MR image can be reconstructed from the k-space matrix populated with values, for example, by means of a multidimensional Fourier transform.

Typically, a magnetic resonance imaging scan is composed of a plurality of individual partial measurements in which raw data is acquired from different slices of the examination subject, from which volume image data can subsequently be reconstructed.

In addition, however, it is also necessary in many examinations to conduct multiple, i.e. a whole series of, magnetic resonance imaging scans of the examination subject, wherein a specific measurement parameter is varied. Based on the measurements, the effect of said measurement parameter on the examination subject is observed in order then subsequently to make diagnostic inferences therefrom. By a series in this context is to be understood at least two, though generally more than two, magnetic resonance imaging scans. In this case it makes sense to vary a measurement parameter such that the contrast of a particular material type excited during the measurements, for example a tissue type of the examination subject or a chemical substance that is significant for most or certain tissue types, such as for example, water, is affected as strongly as possible by the variation of the measurement parameter. This ensures that the effect of the measurement parameter on the examination subject is particularly clearly visible.

A typical example of series of magnetic resonance imaging scans subject to the variation of a measurement parameter strongly influencing the contrast are diffusion imaging methods (also called diffusion-weighted imaging (DWI)). By diffusion is understood the Brownian motion of molecules in a medium. In diffusion imaging, multiple images having different diffusion directions and weightings are generally acquired and combined with one another. The strength of the diffusion weighting is in most cases defined by what is termed the “b-value”. The diffusion images having different diffusion directions and weightings or the images combined therefrom can then be used for diagnostic purposes. Thus, by means of suitable combinations of the acquired diffusion-weighted images it is possible to generate parameter maps having particular diagnostic relevance, such as, for example, maps which reflect the “apparent diffusion coefficient” (ADC) or the “fractional anisotropy” (FA).

Often, the diffusion imaging is based on echo planar imaging (EPI) on account of the short acquisition time of EPI sequences per image and their robustness against movement.

In diffusion-weighted imaging, additional gradients are inserted into a pulse sequence in order to make visible or measure the diffusion properties of the tissue. These gradients lead to tissue exhibiting rapid diffusion (for example, cerebrospinal fluid (CSF)) being subject to a stronger signal loss than tissue exhibiting slow diffusion (for example, grey matter in the brain). The diffusion contrast resulting therefrom is becoming more and more important clinically and in the interim applications go far beyond the classical early detection of ischemic strokes.

Measurements of the diffusion properties in different tissue types by means of magnetic resonance imaging have constituted an indispensable tool of clinical diagnostics for many years now. Typically, use is made in this case of diffusion encoding schemes having two or more diffusion gradients with trapezoidal gradient pulse shapes, as described by Stejskal and Tanner in “Spin Diffusion Measurements: Spin Echoes in the Presence of a Time-Dependent Field Gradient”, J. Chem. Phys. 42: pp. 288-292 (1965), since these a) are efficient in terms of the utilization of the performance limits of a gradient system used and b) can be easily described both in the context of diffusion models and for technical calculations (for example, in respect of simulations or limitations of the gradient system).

More recently, however, there has been an increased level of interest in the research and diagnostics environment in more complex gradient pulse shapes, in particular for tensor-weighted diffusion measurements, which “by design” promise access to new contrast characteristics, as described for example in the article by Szczepankiewicz et al., “Gradient Waveform Design for Tensor-Valued Encoding in Diffusion MRI”, J. Neurosc. Methods 348: p. 109007 (2021).

However, the increasing complexity of the gradient pulse shapes employed in this regard poses major challenges for the preparation, planning and execution of such measurements.

During the processing of measurement protocols by a user, for example, in the course of tensor-weighted diffusion measurements using complex gradient pulse shapes, the user is usually presented with a possible value range in each case for each measurement parameter of a group of measurement parameters that are to be processed. In this case a respective value range is classified for example into at least one of the categories “non-settable parameter values”, “conditionally settable parameter values” and “unconditionally settable parameter values”. The classification into such categories can be displayed to the user in a suitable form, for example color-coded, during the processing of a measurement protocol so that suitable parameter values can be selected for the measurement parameters.

In this case the assignment to a category A (“non-settable parameter value”) can be made if a parameter value of a processed measurement parameter assigned in this category A would lead to a measurement protocol that is not executable. Such parameter values can for example, be blocked for the user so that they cannot be chosen by the user for the corresponding measurement parameter. Nonetheless, parameter values assigned in said category A can be displayed to the user or otherwise brought to the user's attention for example for the case in which they could be settable if the measurement protocol to be processed undergoes an appropriate change at another point, for example, a corresponding change to at least one other measurement parameter of the measurement protocol, in particular one being in a dependency relationship with the processed measurement parameter. Such dependencies of different measurement parameters on one another further increase the complexity of the processing of measurement protocols.

An assignment to a category B (“conditionally settable parameter value”) can be made when a parameter value of a processed measurement parameter assigned in this category B requires an automated, in particular clearly defined, change to a respective parameter value of at least one other measurement parameter than the processed measurement parameter in order to make the measurement protocol executable. The required automated change can be affected for example, as soon as the user sets a parameter value assigned to the category B for a processed measurement parameter such that the adjustments necessary for an executability of the measurement protocol are performed automatically.

An assignment to a category C (“unconditional”) can be made when a parameter value of a processed measurement parameter assigned in this category C has no effect on the executability of the processed measurement protocol. A parameter value of a processed measurement parameter assigned to said category C can be chosen without the need for further adjustment.

Complex calculations are necessary in order to be able to make such an assignment to at least one of the categories A, B or C already during a processing of a measurement protocol by a user, in particular because the respective assignments of possible parameter values to one of the categories A (“non-settable”), B (“conditionally settable”) and C (“unconditionally settable”) can change after each change to a parameter value of a measurement parameter for at least one other measurement parameter, but also for a plurality of other measurement parameters.

The calculations in this case may comprise a check to confirm the executability of a measurement protocol provided for a measurement with regard to the restrictions contingent on the hardware used (hardware limitations), in particular restrictions of a gradient unit used.

Hardware limitations of a gradient unit may comprise, for example: limitations with a time characteristic, such as for example, thermal loadings of gradient power amplifier (GPA) semiconductor components, thermal loadings due to an ohmic loading of GPAs and of feed lines of gradient coils of the gradient unit and/or a power supply line used for the gradient unit; limitations without time characteristic, such as for example, a heat buildup in gradient coils of the gradient unit; and/or limitations with a frequency characteristic, such as for example, mechanical resonances of gradient coils of the gradient unit and/or resonance frequencies of a magnet unit of the magnetic resonance system used, each of which can be described for checking the executability of a measurement protocol using corresponding models with time characteristic, models without time characteristic and models with a frequency characteristic in order to perform the necessary calculations.

For simple trapezoidal gradient pulse shapes, analytical considerations and/or simple approximations are already known by means of which calculations necessary for checking a conformity of a measurement protocol with hardware limitations can be performed sufficiently quickly during a processing of the measurement protocol. For example, in U.S. Pat. No. 8,954,202 B2, US 2020/0150161 A1 or US 2023/0280432 A1, methods for complying with hardware limitations in the course of a diffusion imaging sequence are known. For complex pulse shapes, however, these and other established techniques can no longer be used without due reflection.

Some non-trapezoidal (but more complex) gradient pulse shapes can be approximated by a certain number of trapezoidal gradient pulse shapes. This applies for example to sine- or cosine-type gradient pulse shapes. In this case the necessary calculations can be performed sufficiently quickly as long as the number of halfwaves of the gradient pulse shapes to be approximated is sufficiently small (for example fewer than 100 halfwaves). For more complex gradient pulse shapes, which may be characterized by several hundred or thousand halfwaves, this approach is no longer practicable, however.

It would furthermore be conceivable to ignore some of the aforementioned hardware limitations during the planning of a measurement. For example, in order to ensure compliance with technical hardware limitations, monitoring mechanisms generally integrated into the system of a magnetic resonance facility could be relied upon. A major disadvantage with such an approach, however, is that the executability of a measurement protocol to be used for a measurement cannot be guaranteed at the start of the measurement, so that exceeding hardware limitations during an ongoing measurement may lead to premature termination of the measurement.

Basically, a downstream (for example, one-time) check to confirm an executability of a processed measurement protocol immediately before a start of the measurement would also be conceivable. In this case, however, a user will often be compelled to modify their measurement planning at very short notice (and possibly with a need for significant change to parameter values of measurement parameters). This is scarcely practicable in the clinical environment.

A further option would be to provide measurement protocols tested for executability (with fixed measurement parameters) already prior to a possible measurement, for example, once only at the time of the installation of a magnetic resonance system. In this case, however, there is a lack of the flexibility in the design of the measurement protocols that is necessary in clinical application (for example in terms of a spatial resolution, a number of slices or contrast-determining parameters such as an echo time TE or a repetition time TR) of measurements that are to be conducted individually

As a further possibility deserving of mention is the use of computers with such high levels of computing performance that they are nonetheless capable of performing the described necessary calculations with sufficient speed during a planning of a measurement. The disadvantages of such a solution are not only a high energy overhead during operation but also the costs associated with such high-powered computers.

With regard to the avoidance of certain mechanical resonance frequencies, it is known in the case of periodic gradient pulse sequences (for example an EPI readout module) to block a specific interval of period durations (double the EPI echo spacing) for the user during the measurement planning. However, this simple approach cannot be used for non-periodic gradient pulse sequences.

In order to describe thermal loadings due to hardware limitations with a time characteristic, for example, account models are known in the scope of which a variation of a gradient according to its gradient pulse shape on a gradient axis G_{x/y/z}(t), or the applied current proportional I_{x/y/z}(t) thereto, leads to a loading of an assumed “account” of the gradient unit, and a cooling associated with the gradient unit, for example an active air or water cooling or a passive convection cooling, leads to an unloading of the account.

A loading in a time interval dt of the variation of the gradient according to its gradient pulse shape can in this case be described by means of a load characteristic dS_{x/y/z}(t), an unloading by means of an unload characteristic E_{x/y/z}(dt), for example E_{x/y/z}(dt)=exp(−dt/t_{x/y/z}). For such account models, a measure for the temporal development of the loading S can follow from the following description:

$${S}_{x / y / z} ( t + d t ) = {S}_{x / y / z} ( t ) exp ( - dt / {t}_{x / y / z} ) + d {S}_{x / y / z} ( t ) ( 1 - exp ( - dt / {t}_{x / y / z} ) )$$

For trapezoidal gradient pulse shapes (i.e. gradient pulse shapes having linear ramps and constant plateaus) and typical load characteristics, rapid solutions for a calculation of such loadings are already known, wherein the effect of a complete ramp, or a complete plateau, can be determined in one step in each case. Typical load characteristics in this case are for example (piecewise) linear (n=1) or (piecewise) quadratic (n=2) functions, for example, (using the model parameters α, β and γ as well as limit amplitudes G_{i,x/y/z}):

$$d {S}_{x / y / z} ( t ) = {α}_{x / y / z} {G}_{x / y / z}^{n} ( t )$$

$$\begin{matrix}for & 0 < {G}_{x / y / z} \leq {G}_{0 , x / y / z}\end{matrix} ;$$

$${dS}_{x / y / z} ( t ) = {α}_{x / y / z} {G}_{0 , x / y / z}^{n} + {{β}_{x / y / z} ( {G}_{x / y / z} ( t ) - {G}_{0 , x / y / z} )}^{n}$$

$$for {G}_{0 , x / y / z} < {G}_{x / y / z} \leq {G}_{1 , x / y / z} ;$$

$${dS}_{x / y / z} ( t ) = {α}_{x / y / z} {G}_{0 , x / y / z}^{n} + {{β}_{x / y / z} ( {G}_{1 , x / y / z} - {G}_{0 , x / y / z} )}^{n} + {{γ}_{x / y / z} ( {G}_{x / y / z} ( t ) - {G}_{1 , x / y / z} )}^{n}$$

$$for {G}_{1 , x / y / z} < {G}_{x / y / z} .$$

However, for more complex gradient pulse shapes, as already described above, the necessary calculations likewise become significantly more complex such that these cannot be performed in a clinically acceptable time during a planning of a measurement without special computers having particularly high computing power.

In order to describe loadings due to hardware limitations without time characteristic, it is known in the case of trapezoidal gradient pulse shapes to calculate multiple times during the measurement planning, for example, following specification of a parameter value for a measurement parameter processed in the course of the planning, an average value of the gradient amplitudes to be applied in each case currently in the course of the processed measurement protocol, for example a mean quadratic gradient amplitude, in order to be able to make deductions in a known manner in relation to a heat buildup in gradient coils of the gradient unit.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a schematic flowchart of a method according to the disclosure for acquiring diffusion-weighted measurement data of an examination subject by a magnetic resonance system using a measurement protocol containing non-trapezoidal gradient pulse shapes for the diffusion encoding.

FIG. 2 is a schematic representation of a non-trapezoidal gradient pulse shape on three axes, according to the disclosure.

FIG. 3 is a schematic illustration of a magnetic resonance system according to the disclosure.

The exemplary embodiments of the present disclosure will be described with reference to the accompanying drawings. Elements, features and components that are identical, functionally identical and have the same effect are-insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to provide a method to enable the user to conduct a simplified, where appropriate interactive, planning of measurements using non-trapezoidal gradient pulse shapes for diffusion encoding schemes while taking hardware restrictions into account.

The object may be achieved by a method for acquiring diffusion-weighted measurement data of an examination subject by a magnetic resonance system using a measurement protocol containing non-trapezoidal gradient pulse shapes for the diffusion encoding according to the disclosure, a magnetic resonance system according to the disclosure, a computer program according to the disclosure, and an electronically readable data medium according to the disclosure.

A method according to the disclosure for acquiring diffusion-weighted measurement data of an examination subject by a magnetic resonance system using a measurement protocol containing non-trapezoidal gradient pulse shapes for the diffusion encoding may comprise:
a) loading prepared characteristics for at least one non-trapezoidal gradient pulse shape of the measurement protocol,
b) loading limit values which a hardware unit of the magnetic resonance system must not exceed,
c) assigning possible parameter values of at least one measurement parameter to be set in the measurement protocol to at least one category indicating an executability of the measurement protocol on the magnetic resonance system based on the loaded characteristics while complying with the loaded limit values,
d) inputting at least one desired parameter value of at least one measurement parameter of the measurement protocol while taking the chosen assignment into account,
e) if a parameter value by means of which the measurement protocol is executable has not yet been input for every measurement parameter to be set in the measurement protocol, repeating steps c) and d) until parameter values by means of which the measurement protocol is executable have been input for all the measurement parameters of the measurement protocol that are to be set, and
g) acquiring diffusion-weighted measurement data using the measurement protocol containing the input parameter values.

The loading according to the disclosure of prepared characteristics for at least one non-trapezoidal gradient pulse shape of the measurement protocol permits a rapid assignment of possible parameter values to a category indicating an executability of the measurement protocol on the magnetic resonance system while complying with the loaded limit values. As a result of the assignment to the at least one category, it is made easier for a user, during the planning of a measurement that is to be conducted, to find parameter values for measurement parameters that are to be set in a measurement protocol that is to be used which conform to the limit values given by the hardware of the magnetic resonance system, and consequently to obtain a measurement protocol that is executable on the magnetic resonance system using the chosen parameter values.

The prepared characteristics of the non-trapezoidal gradient pulse shapes are suitable for performing the assignment to the at least one category. Examples of such characteristics follow below. Calculations that were required for determining the characteristics of the non-trapezoidal gradient pulse shapes can be omitted during a planning of a measurement that is to be conducted, as a result of which this process can be performed faster and with less computational overhead.

During this process, characteristics for any pulse shapes can be prepared without particular specifications in terms of their design (for example, a periodicity). The characteristics of the non-trapezoidal gradient pulse shapes can be determined on any desired computing unit and at any point in time prior to a measurement that is to be conducted such that already when a magnetic resonance system is commissioned, or also at any time following commissioning, prepared characteristics for non-trapezoidal gradient pulse shapes can be loaded for example, into a memory of the magnetic resonance system.

Overall, therefore, the method described herein facilitates and speeds up a discovery of parameter values for measurement parameters of a measurement protocol by means of which the measurement protocol is executable on a magnetic resonance system during a planning of a measurement that is to be performed by means of the magnetic resonance system.

A magnetic resonance system according to the disclosure may comprise a magnet unit, a gradient unit, a radiofrequency unit (collectively referred to as a scanner), and a controller, which may comprise an assignment unit (assigner) and configured to perform a method according to the disclosure.

A computer program according to the disclosure implements a method according to the disclosure on a controller when the program is executed on the controller. For example, the computer program may comprise commands which, when the program is executed by a controller, for example, a controller of a magnetic resonance system, cause said controller to perform a method according to the disclosure. The controller can be designed in the form of a computer.

In this case the computer program can also be present in the form of a computer program product which can be loaded directly into a memory of a controller and may comprise program code means for performing a method according to the disclosure when the computer program product is executed in a computing unit of the controller.

A computer-readable storage medium according to the disclosure may comprise commands which, when executed by a controller, for example, a controller of a magnetic resonance system, cause the controller to perform a method according to the disclosure.

The computer-readable storage medium may be embodied as an electronically readable data medium comprising electronically readable control information stored thereon which may comprise at least one computer program according to the disclosure and is embodied such that when the data medium is used in a controller of a magnetic resonance system it performs a method according to the disclosure.

The advantages and statements disclosed in relation to the method apply analogously also to the magnetic resonance system, the computer program product and the electronically readable data medium.

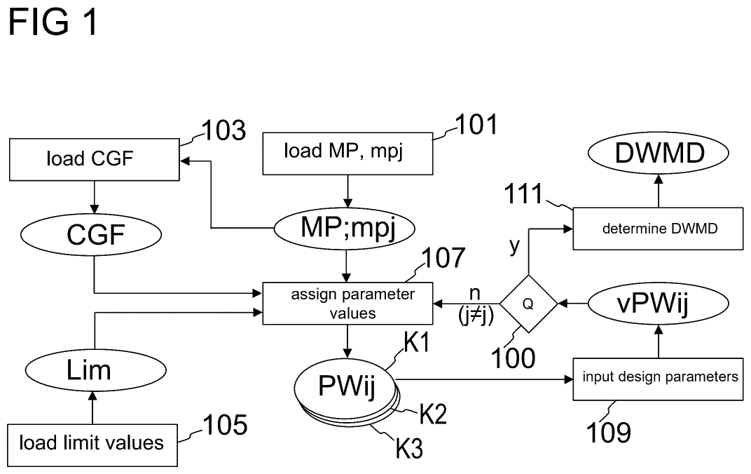

FIG. 1 is a schematic flowchart of a method according to the disclosure for acquiring diffusion-weighted measurement data of an examination subject by means of a magnetic resonance system using a measurement protocol containing non-trapezoidal gradient pulse shapes for the diffusion encoding.

The measurement protocol MP to be used may comprise settable measurement parameters mpj and can be chosen and/or loaded in advance by a user (block 101).

Prepared characteristics CGF for at least one non-trapezoidal gradient pulse shape GF of the measurement protocol MP are loaded (block 103). In this case a user can choose in advance at least one non-trapezoidal gradient pulse shape that is to be used, for example from a list of non-trapezoidal gradient pulse shapes for the measurement protocol MP, to ensure that only characteristics for the chosen non-trapezoidal gradient pulse shapes are loaded.

In this case it is possible to use so-called “balancing” methods, as described for example in U.S. Pat. No. 11,609,289B2 or US20230280432A1 for “classical” diffusion encoding schemes employing trapezoidal gradient pulse shapes, and which avoid temporary load peaks in measurement protocols MP for the acquisition of diffusion-weighted measurement data DWMD by choosing for example, the diffusion direction and/or diffusion weighting between succeeding diffusion encoding sequences in such a way that a maximally homogeneous distribution of the loading of the axes of the gradient unit with respect to time is achieved and the loading on one or more axes of the gradient unit is reduced on average over the different diffusion encoding sequences to be performed in the course of the measurement protocol MP. Methods of said type can be used without restriction also for diffusion encoding schemes containing non-trapezoidal gradient pulse shapes.

The prepared characteristics CGF of the non-trapezoidal gradient pulse shapes GF are suitable for performing the assignment to the at least one category K1, K2, K3.

For example, the loaded characteristics may comprise at least one value from the group consisting of a characteristic time period, a guidance value for an amplitude (for example, a mean quadratic gradient amplitude) and an energy spectrum. More details on this are given below.

Limit values Lim which a hardware unit, in particular the gradient unit 5, of the magnetic resonance system 1 must not exceed are loaded (block 105).

Possible parameter values PWij of at least one measurement parameter mpj to be set in the measurement protocol MP are assigned to at least one category K1, K2, K3 indicating an executability of the measurement protocol MP on the magnetic resonance system 1 based on the loaded characteristics CGF while complying with the loaded limit values Lim (block 107).

The at least one category K1, K2, K3 can be a category that specifies unconditionally settable parameter values. Possible parameter values PWij can for example be assigned also to the above-described categories A (“non-settable”), B (“conditionally settable”) and C (“unconditionally settable”) as categories K1, K2, K3. Depending on the use case, however, more or fewer categories may also be used to which basically possible parameter values PWij of the measurement parameter mpj are assigned.

The assignment can be indicated to a user, for example by means of a color code or another specific indicator, for example, an exclusive display of “unconditionally settable parameters”.

At least one desired parameter value vPWij is input (block 109) considering the chosen assignment of the possible parameter values PWij of the measurement parameters mpj of the measurement protocol MP. This can be entered by a user or automatically. By taking into account the chosen assignment of the possible parameter values PWij of the measurement parameters mpj of the measurement protocol MP to at least one category K1, K2, K3 specifying an executability of the measurement protocol MP on the magnetic resonance system 1 while complying with the loaded limit values Lim, it can be ensured that the input parameter values vPWij of the measurement parameters mpj of the measurement protocol are executable on the magnetic resonance system 1 within the limit values Lim.

By means of a query 100 it can be determined whether a parameter value vPWij by means of which the measurement protocol is executable has already been set for each measurement parameter mpj to be set from the measurement protocol MP. If this is not the case (query 100, n), at least for measurement parameters mpj for which no parameter value vPWij has yet been set (j≠j), possible parameter values PWij of at least one measurement parameter mpj to be set from the measurement protocol MP are again assigned to the at least one category K1, K2, K3 specifying an executability of the measurement protocol MP on the magnetic resonance system 1 based on the loaded characteristics CGF while complying with the loaded limit values Lim (block 107). In this case input parameter values vPWij can be considered such that the assignment may change if necessary. By taking into account the chosen (new) assignment of the possible parameter values PWij of the measurement parameters mpj of the measurement protocol MP, at least one desired parameter value vPWij is input (block 109) until parameter values vPWij by means of which the measurement protocol MP is executable have been input for all measurement parameters mpj to be set from the measurement protocol MP.

By using the measurement protocol MP with the input parameter values vPWij, diffusion-weighted measurement data DWMD is acquired and processed further if necessary.

The diffusion-weighted measurement data DWMD to be acquired is in this case in particular nonlinear diffusion-weighted measurement data DWMD, for example track-weighted and/or spherical diffusion-weighted measurement data DWMD.

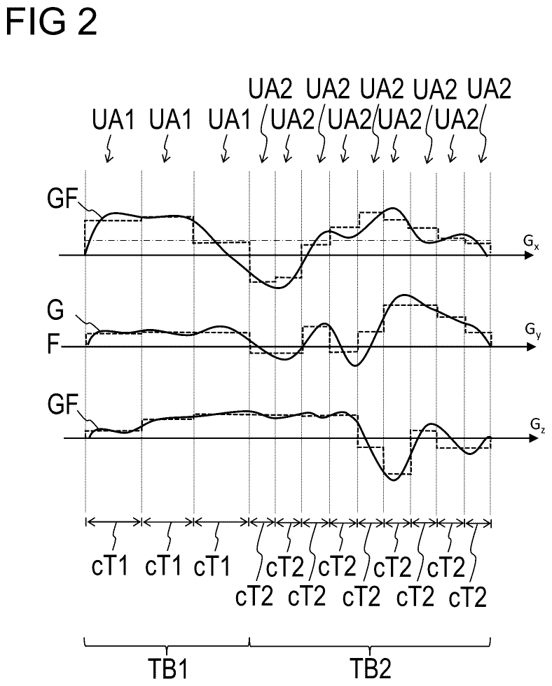

FIG. 2 is a schematic and exemplary representation in the k-space of a non-trapezoidal gradient pulse shape GF shown as a continuous curve in its variation with time on three axes Gx, Gy, Gz of a coordinate system which correspond for example to the axes x, y, z of a gradient unit 5 of a magnetic resonance system 1. The non-trapezoidal gradient pulse shape GF may also be defined on just one or two axes Gx, Gy, Gz. “Non-trapezoidal”, within the meaning of the method, are gradient pulse shapes GF which cannot be composed of shapes corresponding to a trapezoid, but for example, have a more complex, in particular nonlinear, variation on at least one axis Gx, Gy, Gz.

In order to calculate the characteristics CGF, a gradient pulse shape GF may be defined as a normalized gradient pulse shape f whose amplitude is scaled during the measurement planning, for example, as a settable measurement parameter mpj, to a desired value by multiplication by a factor G in order to generate a desired diffusion encoding sequence such that a calculation of a loading generated by means of a gradient having the gradient pulse shape GF can be performed with the scaled gradient pulse shape GF=G*f.

It is also conceivable that the at least one non-trapezoidal gradient pulse shape GF is defined along at least one axis Gx, Gy, Gz extending in a direction of a logical coordinate system. In this case the axes of the logical coordinate system can correspond, for example, to the axes of a planned image volume from which diffusion-weighted measurement data DWMD is to be acquired, and/or to the planned diffusion directions. The gradient pulse shape GF can then be transformed from the logical coordinate system by means of a suitable rotation matrix into the coordinate system of the axes x, y, z of the gradient unit 5 in order to enable loadings on the physical axes x, y, z to be calculated.

The assignment of the possible parameter values PWij to the at least one category K1, K2, K3 may comprise a calculation of at least one loading on at least one axis Gx, Gy, Gz which correlates with currents required by a switching of the gradient pulse shape GF on the respective axis. If the coordinate system of the axes Gx, Gy, Gz of the gradient pulse shape does not correspond to a coordinate system of a magnetic resonance system 1, in particular the gradient unit 5 thereof, the calculation of the loading may comprise a transformation from the coordinate system of the gradient pulse shape into a coordinate system of the magnetic resonance system such that the loadings are present in the axes x, y, z of the magnetic resonance system.

A (predetermined) scaling factor can be assigned to the at least one non-trapezoidal gradient pulse shape GF per axis Gx, Gy, Gz on which it is defined such that it can be adjusted in its amplitude, in its profile and in its associated characteristics in accordance with the scaling factor.

In this case, instead of a description of different non-trapezoidal gradient pulse shapes GF for the measurement protocol MP on the three axes Gx, Gy, Gx, it can be provided to use like profiles of non-trapezoidal gradient pulse shapes GF with different scalings fx, fy, fz for at least one of the three axes Gx, Gy, Gz such that the profile of an amplitude of a gradient G(t) having the gradient pulse shape GF with a normalized profile f(t) and an amplitude G can be written as:

$$G ( t ) = G f ( t ) ( fx , fy , fz ) .$$

It is also conceivable to define a non-trapezoidal gradient pulse shape GF in this case only on one axis, for example on the Gx axis G(t)=G(fx(t), 0, 0). This approach permits in particular the combination of non-trapezoidal gradient pulse shapes GF with “diffusion directions” in the conventional sense. The diffusion directions are in this case described by means of a set of N vectors Vn=(vn,x, vn,y, vn,z), and the gradient pulse shapes GF to be applied sequentially in the course of the measurement protocol MP are yielded from:

$$GFn ( t ) = Gf ( t ) Vn .$$

When a loading generated by means of a gradient having the gradient pulse shape GF is determined, it may suffice in this case to consider only the maximum single-axis loadings Gmax,x(t)=G f(t) (max(vn,x), 0, 0), Gmax,y(t)=G f(t) (0, max(vn,y), 0), Gmax,z(t)=G f(t) (0, 0, max(vn,xz)) and in this way further reduce the computational overhead during the measurement planning.

The loaded characteristics CGF may comprise characteristic subsections UA1, UA2 of the gradient pulse shape GF into which the gradient pulse shape GF is deconstructed.

Characteristic subsections UA1, UA2 can be determined based on a characteristic time period cT1, cT2. Determining a characteristic time period cT1, cT2 may comprise conducting a frequency analysis of the gradient pulse shape GF and determining a cutoff frequency F of the gradient pulse shape GF. The cutoff frequency F can be determined for example in such a way that a predetermined percentage, for example 20%, in particular 10%, of a pulse energy applied by means of the gradient pulse shape GF in a frequency band above the cutoff frequency F is applied. The characteristic time period cT1, cT2 can now be chosen as a function of the respective cutoff frequency F such that the dominant portions of the gradient pulse shape GF in terms of energy are acquired with sufficient accuracy. For this purpose it may be sufficient to determine a characteristic time period cT1, cT2 as the inverse of the respective cutoff frequency F, preferably as the inverse of double the respective cutoff frequency F, such that for example, cT1=1/(2*F) is yielded for a characteristic time period cT1. If a cutoff frequency F lies at 400 Hz, for example, a characteristic time period cT1 of 1.25 ms can be obtained in this way. A non-trapezoidal gradient pulse shape having a duration of 75 ms can accordingly be subdivided into 75/1.25=60 subsections UA1 of constant amplitude, as a result of which the number of necessary calculations of a loading is 60. Compared to the calculations required in prior art methods for a gradient pulse shape GF of a duration of 75 ms with a time grid of for example 10 μs for 7500 sections, this represents an enormous reduction in the computational load.

Alternatively, it can be provided as a first step to specify a fixed characteristic time period cT1, for example at 1 millisecond (ms). Assuming the above-cited inverse proportionality to double the cutoff frequency F, a cutoff frequency F can be determined by means of the specified characteristic time period cT1 by F=1/(2*cT1). Given a characteristic time period cT1 of 1 ms, the result for the cutoff frequency F would therefore be 500 Hz. It can be checked based on the cutoff frequency F determined from the specified characteristic time period cT1 whether the main portion of a pulse energy applied by means of the gradient pulse shape GF (for example 80% or 90%) lies below the determined cutoff frequency F. If this is not the case, the use of this gradient pulse shape GF can be refused (with a corresponding indication) and/or another gradient pulse shape GF which meets this condition can be proposed. Alternatively, a permissible maximum amplitude of the gradients for the acquisition of the diffusion-weighted measurement data DWMD can be limited. Clinical applications generally operate with gradient pulse shapes GF in which the dominant energy fraction lies below 200 Hz, so the choice of a fixed cutoff frequency F of 500 Hz is by all means feasible.

A further option for determining a cutoff frequency F from an energy spectrum of the gradient pulse shape GF is described hereinbelow.

In order to determine its characteristics, a gradient pulse shape can be subdivided into subareas TB1, TB2, and a characteristic time period cT1, cT2 which subdivides the respective subarea TB1, TB2 of the gradient pulse shape GF into as few characteristic subsections UA1, UA2 as possible can be determined for each subarea TB1, TB2. Such a subdivision into subareas TB1, TB2 is advantageous in particular for heterogeneous gradient pulse shapes GF comprising subareas TB1 having slowly varying amplitude and subareas TB2 having rapidly varying amplitude of the gradients.

A respective constant amplitude can be determined for each individual characteristic subsection UA1, UA2 of the characteristic subsections UA1, UA2, which constant amplitude corresponds as closely as possible to a loading in the respective subsection caused on the respective axis Gx, Gy, Gz by the gradient pulse shape GF. In FIG. 2, respective constant amplitudes of the individual subsections UA1, UA2 are represented by dashed lines.

Determining a constant amplitude for a subsection UA1, UA2, may comprise forming a mean value of the amplitude of the gradient pulse shape GF in the subsection UA1, UA2 or forming a weighted, for example, weighted according to a load characteristic, mean value of the amplitude of the gradient pulse shape GF in the subsection UA1, UA2 or determining a maximum value of the amplitude of the gradient pulse shape GF in the subsection UA1, UA2.

Generally, the respective constant amplitudes should be chosen in such a way that the resulting approximation of the gradient pulse shape GF in the piecewise constant subsections UA1, UA2 characterizes a loading generated by means of a gradient having the gradient pulse shape GF with sufficient accuracy.

In a simple case, the constant amplitudes of a subsection UA1, UA2 can easily be determined using a mean value of the amplitude G(t) of the gradient pulse shape GF in the subsection UA1, UA2. Accordingly, a constant amplitude Gx in a subsection UA1 of the characteristic time period cT1 starting at a time point tk can be written for example, as:

$${G}_{k} = 1 / {T}_{tk} {ò}^{tk + cT 1} dtG ( t ) .$$

It is also conceivable to work with a weighting W(G) fitted for example, to a load characteristic of an account model used for a calculation of a loading such that the constant amplitude in a subsection UA1 of the characteristic time period cT1 starting at the time point tk is yielded as:

$${G}_{k} = {}_{tk} {ò}^{tk + c T 1} d t W ( G ( t ) ) G ( t ) {/}_{tk} {ò}^{tk + c T 1} d t W ( G ( t ) ) .$$

Such a weighting W can be chosen as a function of the amplitude G(t) of the gradient pulse shape GF, for example, equal to the amplitude G(t) of the gradient pulse shape GF, such that the following applies:

$$W ( G ( t ) ) = G ( t ) ,$$

or, in order to obtain a quadratic weighting W, chosen equal to the square of the amplitude G(t) of the gradient pulse shape GF such that the following then applies:

$$W ( G ( t ) ) = {G}^{2} ( t ) .$$

It is furthermore conceivable, effectively as a “worst case” in each subsection UA1, UA2, to use the maximum value of the magnitude of the amplitude G(t) of the gradient pulse shape GF in the respective subsection UA1, UA2.

In all cases it can be provided, when determining a mean value of the amplitude G(t) of the gradient pulse shape GF, to use the magnitude of the amplitude |G(t)| instead of the amplitude G(t) itself. This leads to a more conservative consideration of intervals and subsections UA1, UA2 in which the amplitude G(t) of the gradient pulse shape GF has one or more zero crossings.

Again alternatively, the determination of a mean value of the amplitude G(t) of the gradient pulse shape GF could be performed in each interval or subsection UA1, UA2 initially also independently for positive and negative amplitudes G(t), and then the greater value or the greater magnitude used as the constant amplitude of the respective subsection UA1, UA2.

With a piecewise constant representation of the non-trapezoidal gradient pulse shape GF obtained in the subsections UA1, UA2 with their respective constant amplitudes, a loading generated by means of a gradient having the gradient pulse shape GF can be performed within the scope of known modelings with account models having a time characteristic, wherein calculations of a loading are performed for each subsection UA1, UA2 analogously to an already known sequence of trapezoidal gradient pulse shapes having a ramp duration of 0 and a plateau duration of the characteristic time period cT1 or cT2. Accordingly, it is furthermore also possible without problems to determine a loading generated by means of trapezoidal and non-trapezoidal gradient pulse shapes combined (and taking account of the chronology) and to assign ranges of parameter values PWij of measurement parameters mpj of the measurement protocol MP correspondingly to a suitable category K1, K2, K3.

A loading caused by the gradient pulse shape GF can be calculated or estimated based on such determined characteristic subsections UA1, UA2 and their associated constant amplitudes.

If the non-trapezoidal gradient pulse shape GF is defined on axes Gx, Gy, Gz in a logical coordinate system that does not correspond to the physical coordinate system of the axes x, y, z of the gradient unit 5, then the subsections UA1, UA2 together with their associated constant amplitudes can be transferred by means of a suitable rotation matrix from the axes Gx, Gy, Gz into a suitable coordinate system. For example, if the gradient pulse shape GF is defined in a logical coordinate system with readout encoding direction Gx, phase encoding direction Gy and slice encoding direction Gz, but a check on executability must be performed in physical coordinates of the axes x, y, z of the gradient unit, a gradient vector Gk=(Gk,Gx Gk,Gy Gk,Gz) describing the gradient pulse shape GF can be transformed for each subsection UA1, UA2 by means of the suitable rotation matrix R according to:

$$G ‘ k = ( G ‘ k , xG ‘ k , yG ‘ k , z ) = RGk .$$

G′k for example, in the physical coordinate system of the axes x, y, z of the gradient unit 5.

Analogously, it can be provided to take into account an additional rotation of the gradient pulse shape GF according to a direction assignment. This corresponds to the known “diffusion directions” in conventional (linear) diffusion encoding schemes. With M different direction assignments of a measurement of diffusion-weighted measurement data DWMD, these can be described by means of rotation matrices Zm such that gradient vectors Gk,m transformed according to the direction assignments can be obtained from:

$$Gk , m = ZmGk .$$

A combination with the above-described coordinate transformation is easily possible, where the following applies:

$$G ‘ k , m = RZmGk .$$

In the calculation of a loading due to the gradient pulse shape GF, it may be necessary to check several (or even all M) direction assignments in succession since the distribution of the energy to the three physical axes x, y, z of the gradient unit may be different in each case.

In this case the characteristic time period cT1, cT2 should be chosen such that the piecewise constant sections continue to characterize the loading generated by the gradients of the gradient pulse shape GF with sufficient accuracy. At the same time, the characteristic time period cT1, cT2 must be as long as possible in order to generate as small a number of subsections UA1, UA2 as possible. A smaller number of subsections UA1, UA2 permits a faster calculation of a loading generated by gradients having the gradient pulse shape GF.

The assignment of the possible parameter values PWij to the at least one category K1, K2, K3 may comprise a section-wise calculation according to the subsections UA1, UA2 of a loading according to a corresponding account model (with time characteristic), for example for a gradient power amplifier (GPA), in particular its semiconductor components, feed cables, filter components and/or power supply.

Such a deconstruction of the gradient pulse shape GF is advantageous in particular for a determination of a loading which is subject to a time characteristic and which is therefore calculated using account models with a time characteristic since a number of necessary computing operations during the calculation of a loading can be significantly reduced as a result of the deconstruction into characteristic subsections UA1, UA2 having respective constant amplitudes, and the simplification of the gradient pulse shape GF achieved therewith.

Account models having a time characteristic are characterized in that the loading of components by gradient pulse shapes Gx/y/z(t) succeeds with sufficient accuracy only with explicit consideration of the time dependence. In this regard, in particular the temporal sequence of a preceding gradient activity (history) can have an effect on the executability of a gradient pulse shape.

Examples of hardware components that may be modeled with a time characteristic may include:
semiconductor components of the gradient power amplifiers (GPAs), which are characterized in that they have short time constants (approx. 1 . . . 100 milliseconds), must be modeled separately for each axis x, y, z of the gradient unit while further taking into account positive and negative amplitudes of the gradients,
feed cables and filter components of the GPAs, which are subject to ohmic losses and have long time constants (approx. 1 . . . 100 seconds), which must likewise be modeled separately for each axis x, y, z of the gradient unit with a joint consideration of positive and negative amplitudes of the gradients, and
a power supply line for the power supply of the gradient unit which is characterized by short time constants (approx. 1 . . . 100 milliseconds) and permits a joint consideration of all the axes of the gradient unit and a joint consideration of positive and negative amplitudes of the gradients.

Account models for describing thermal loadings of the aforesaid type are known. A number of examples are mentioned above in the introduction.

In order to speed up further a measurement preparation during which characteristics CGF of the gradient pulse shape GF can be determined, a one-time determined deconstruction of a gradient pulse shape GF into subsections UA1, UA2 having respective constant amplitudes which represent the gradient pulse shape GF section by section for calculations of different loadings, in particular using account models with time characteristic, can be used. For example, a deconstruction with the same time period cT1, cT2 and constant amplitudes Gk in subsections UA1, UA2 can be used both for a calculation of a loading of GPA semiconductor components and for a calculation of ohmic loadings.

In the case of account models which jointly consider a plurality of axes, for example in a modeling of the power supply, amplitudes G²k,x, G²k,y, G²k,z can be calculated in order to determine the loading in each subsection UA1, UA2 starting at tk, for example transformed onto the physical coordinate system of the gradient unit, with the sum of squares of the constant, such that G²k=G²k,x+G²k,y+G²k,z is yielded.

If a loading to be determined generated by a gradient having the gradient pulse shape GF has an additional frequency dependence, for example due to a frequency-dependent resistance of a coil of the gradient unit, this can be taken into consideration for example by means of an additional factor F_{GC}(w) by means of which the constant amplitudes of the representation of the gradient pulse shape GF are scaled during a calculation using a corresponding account model. For non-trapezoidal pulse shapes, a characteristic frequency, for example, the mean value of a frequency band in which the highest energy is applied, can be assumed for this purpose for example, which characteristic frequency is determined once only during the preparation of the measurement. Alternatively, the previously mentioned cutoff frequency F can be used.

The time-consuming steps of determining characteristic time periods cT1, cT2 and deconstructing a gradient pulse shape GF into characteristic subsections UA1, UA2 and determining the constant amplitudes for the individual subsections UA1, UA2 can be performed before the beginning of a measurement planning process. Loaded characteristics may therefore comprise at least one of the variables from the group of the determined characteristic time periods cT1, cT2, of the characteristic subsections UA1, UA2 and their respective constant amplitudes.

A loading according to the disclosure of prepared characteristics CGF already described during a measurement preparation permits a rapid calculation of loadings by means of account models with time characteristic and consequently a rapid (possibly interactive) measurement planning. In this case arbitrary gradient pulse shapes, without restrictions in terms of their design, can be chosen and executable parameter values PWij for measurement parameters mpj of a measurement protocol MP can quickly be determined, wherein a high degree of accuracy in the assignment of the parameter values PWij to the at least one category K1, K2, K3 can be achieved by precisely coordinated approximations over a time grid of characteristic time periods cT1, cT2 and the constant amplitudes in the subsections UA1, UA2. Even rotations can be considered without performance penalties.

In addition or alternatively, the loaded characteristics CGF may comprise a normalized guidance value for an amplitude of the gradient pulse shape GF over its entire course. A guidance value of said type is represented by way of example as a dash-dotted line for the axis Gx in FIG. 2.

The normalized guidance value can be determined based on an averaged, for example, mean quadratic, amplitude G(t) of the gradient pulse shape and where applicable of background gradients, in particular per axis Gx, Gy, Gz of the gradient unit 5 of the magnetic resonance system 1. Other averaging techniques may be used in an analogous manner in addition to quadratic mean values.

As normalized guidance values, for example, for all chosen non-trapezoidal gradient pulse shapes GF having an amplitude G_{x/y/z}(t)=G f_{x/y/z}(t), normalized values fᵣₘₛ can be calculated for this purpose as follows:

$${f}_{r m s , x / y / z} = sqrt ( 1 / {T}_{0} {\int }^{T} dt {f}_{x / y / z}^{2} ( t ) ) ,$$

where T is equal to the duration of the gradient pulse shape GF.

The consideration of normalized values makes sense since the diffusion weighting (b-value) of the subsequent measurement, and consequently the actual gradient amplitude G(t), is not yet known at the time of the measurement preparation. Given the presence of the amplitude values G(t) on a grid (G_{x/y/z}(t) à G_{x/y/z}(tₖ)), the integral is simplified to a summation.

The assignment of the possible parameter values PWij to the at least one category K1, K2, K3 can then comprise a calculation of a loading according to a corresponding account model (without time characteristic) using the desired diffusion weighting by the gradient pulse shape GF.

Normalized guidance values can be determined for an amplitude of the gradient pulse shape GF for a planned set of different diffusion weightings (b-values) and/or diffusion directions.

From the normalized guidance values for the set of different diffusion weightings (b-values) and/or diffusion directions, an averaged normalized guidance value (instead of the individual normalized guidance values for the set) for the amplitude of the gradient pulse shape GF can be loaded as a characteristic and the assignment of the possible parameter values PWij to the at least one category K1, K2, K3 can be made based on the averaged normalized guidance value.

Such normalized guidance values for amplitudes of a gradient pulse shape GF are in particular of advantage for determining a loading which is not subject to any time characteristic and which is therefore calculated using account models without time characteristic since the normalized guidance values have been determined in advance and can easily be used during a measurement planning.

Based on the normalized guidance values as characteristics, during a measurement planning with a now known amplitude G(t) of the gradient pulse shape, the contribution of a non-trapezoidal gradient pulse shape to a, for example, quadratic, mean value Gᵣₘₛ of a gradient pulse shape GF can be easily and quickly determined successively on an axis-specific basis.

This can be achieved for an axis, for example, according to the following pseudocode:

| - | Gₘₛ = 0 | |
|---|---|---|
| - | Tₜₒₜₐₗ = 0 | |
| - | For (i = 0 ... N − 1) | // loop over all subsections UA1, UA2 |

| | |
|---|---|
| ∘ | If (trapezoidal) |

| | | |
|---|---|---|
| □ | Gₘₛ = Gₘₛ + G_{ms,trap} * Tₜᵣₐₚ | // as known |

| | |
|---|---|
| □ | Tₜₒₜₐₗ = Tₜₒₜₐₗ + Tₜᵣₐₚ |

| | |
|---|---|
| ∘ | Else |

| | |
|---|---|
| □ | Gₘₛ = Gₘₛ + G*G * fᵣₘₛ*fᵣₘₛ * T // new with normalized guidance |
| | values fᵣₘₛ |
| □ | Tₜₒₜₐₗ = Tₜₒₜₐₗ + T |

| | |
|---|---|
| - | Gᵣₘₛ = sqrt(Gₘₛ / Tₜₒₜₐₗ) |

In the measurement planning, the loading can thus be determined quickly by means of arbitrary combinations of trapezoidal and non-trapezoidal gradient pulse shapes and parameter values PWij of measurement parameters mpj of the measurement protocol MF marked correspondingly, for example, as value ranges. For this purpose, the calculated Gᵣₘₛ values can be compared with predefined limit values Gₘₐₓ included in the limit values lim which result from the design of the gradient coil used in the gradient unit, for example as follows:

$$gradient coil , single axis : {G}_{r m s , x , z} £ {G}_{max , x , y , z}$$

$$gradient coil , all axes : {G}_{r m s , x}^{2} + {G}_{rms , y}^{2} + {G}_{rms , z}^{2} £ {G}_{max}^{2}$$

If at least one of these conditions is met, the measurement in relation to the respective hardware characteristic can be conducted.

If, during the time period T of a gradient pulse having a non-trapezoidal gradient pulse shape GF, a constant background gradient G_{off,x/y/z} is applied, for example for shim purposes, the amplitudes of the gradient pulse of the gradient pulse shape GF and of the background gradient are added to G_{off,x/y/z}+G f_{x/y/z}(t). Accordingly, a determination of normalized guidance values, for example, as mean values, requires an additional precalculation of normalized mean values fₘₑₐₙ, where the following applies:

$${f}_{mean , x / y / z} = 1 / {T}_{0} {ò}^{T} dt {f}_{x / y / z} ( t ) .$$

With (G_{off,x/y/z}+G f_{x/y/z}(t))²=G²_{off,x/y/z}+2G_{off,x/y/z}G f_{x/y/z}(t)+G² f²_{x/y/z}(t), the calculation changes according to the following pseudocode for an axis:

| - | Gₘₛ = 0 | |
|---|---|---|
| - | Tₜₒₜₐₗ = 0 | |
| - | For (i = 0 ... N − 1) | // loop over all subsections UA1, UA2, UA3 |

| | |
|---|---|
| ∘ | If (trapezoidal) |

| | | |
|---|---|---|
| □ | Gₘₛ = Gₘₛ + G_{ms,trap,offset} | * Tₜᵣₐₚ // as known |

| | |
|---|---|
| □ | Tₜₒₜₐₗ = Tₜₒₜₐₗ + Tₜᵣₐₚ |

| | | |
|---|---|---|
| ∘ | Else | // new with normalized guidance |

values

| | |
|---|---|
| □ | Gₘₛ = Gₘₛ + (G_{off}*G_{off} + 2 * G_{off} * G*fₘₑₐₙ + G*G * fᵣₘₛ*fᵣₘₛ) * T |
| □ | Tₜₒₜₐₗ = Tₜₒₜₐₗ + T |

| | |
|---|---|
| - | Gᵣₘₛ = sqrt(Gₘₛ / Tₜₒₜₐₗ) |

Such a background gradient can be set in this case either to the actual (axis-specific) value, or, preferably, to an assumed maximum value. The latter has the advantage that a protocol remains executable irrespective of the current shim state.

When background gradients are considered, it is important to consider their polarity, for example by performing separate calculations with “positive” and “negative” gradient amplitude. The term 2*G_{off}*fₘₑₐₙ in the pseudocode above is responsible for this.

Account models without time characteristics are characterized in that a loading of components of the gradient unit due to gradient pulse shapes GF (G_{x/y/z}(t)) without taking into account the detailed time dependency with sufficient accuracy succeeds such that above-described normalized guidance values are well-suited for a calculation of a loading.

Examples of limit values Lim of a hardware unit of a magnetic resonance system which can normally be modeled without time characteristic are:
a mean quadratic gradient amplitude for individual axes, and
a mean quadratic gradient amplitude for the totality of the axes,
   by means of which ohmic power losses of gradient coils of a gradient unit 5 are determined.

As in the case of modelings using account models with time characteristic, rotations, for transformation between different coordinate systems and/or for direction assignments, can also be taken into consideration in modelings using account models without time characteristic. It is important to note here that the rapid calculation of normalized guidance values of a gradient pulse shape GF with G(t)=G f(t) (with the elements Gᵢ(t)=G fᵢ(t), i Î {x, y, z}) following application of a rotation matrix R (with the elements Rᵢⱼ, i,j Î {x, y, z}) may require further precalculations. An example of quadratic mean values is shown as follows:

$$Applies without rotation : {G}_{rms , i}^{2} = 1 / T {G}^{2} {S}_{k} {f}_{i}^{2} ( {t}_{k} )$$

$$and with rotation : {f}_{i}^{′} ( {t}_{k} ) = {S}_{j} {R}_{i j} {f}_{j} ( {t}_{k} ) ,$$

$$follows : {G}_{r m s , i}^{′2} = 1 / T {G}^{2} {{S}_{k} ( {S}_{j} {R}_{i j} {f}_{j} ( {t}_{k} ) )}^{2} = 1 / T {G}^{2} {S}_{k} {S}_{j} {R}_{i 1} {f}_{j} ( {t}_{k} ) {f}_{1} ( {t}_{k} ) = 1 / T {G}^{2} {S}_{j} {S}_{1} {R}_{i j} {R}_{i 1} ( {S}_{k} {f}_{j} ( {t}_{k} ) {f}_{1} ( {t}_{k} ) )$$

For this purpose, the sums of the form Sₖ fⱼ(tk) fₗ(tₖ) can also be calculated for all combinations j,l Î {x, y, z} already in the course of the measurement preparation and be loaded for example, as characteristics CGF. In this way, quadratic mean values can quickly be determined for any desired rotations of the gradient pulse shapes GF during the measurement planning.

For identical non-trapezoidal gradient pulse shapes GF on all axes Gₙ(t)=G f(t) Vₙ with the direction vectors Vₙ=(v_{n,x}, v_{n,y}, v_{n,z}), the determination is simplified to:

$${G}_{r m s , i}^{′2} = 1 / T {G}^{2} {{S}_{k} ( {S}_{n} {v}_{n , i} f ( {t}_{k} ) )}^{2} = 1 / T {G}^{2} {S}_{k} {f}^{2} ( {t}_{k} ) {S}_{n} {v}_{n , i} {S}_{m} {v}_{m , i}$$

In the course of the measurement preparation it is therefore sufficient to precalculate normalized mean values of the form Sₖ f²(tₖ) as normalized guidance values of the gradient pulse shape GF. The direction vectors (Sₙ v_{n,i} Sₘ v_{m,i}) can be considered either during the measurement preparation or (quickly and without great computational overhead) during the measurement planning.

Analogously to the above-described modelings using account models with time characteristic, an additional frequency dependence, for example by means of an additional factor F_{GC}(w), can also be considered in modelings using account models without time characteristic.

As is already known for trapezoidal gradient pulse shapes, the scalings and/or rotations being performed during the subsequent measurement can also be considered in a mean value determination for non-trapezoidal gradient pulse shapes GF during the measurement planning. For example, mean values for the different desired b-values and/or direction assignments of the measurement can be determined initially, from which overall mean values are then determined. The overall mean values can be called upon in models without time characteristic for the assignment of parameter values PWij, for example, in value ranges, of the measurement parameters mpj of the measurement protocol MP.

A loading according to the disclosure of prepared characteristics CGF already described during a measurement preparation permits a fast calculation of loadings using account models without time characteristic and consequently a rapid (possibly interactive) measurement planning. In this case arbitrary gradient pulse shapes, without restrictions in terms of their design, can be chosen and executable parameter values PWij for measurement parameters mpj of a measurement protocol MP can quickly be determined, wherein additional background gradients and rotations can also be considered easily and without performance penalties.

In addition, frequency-dependent loadings of a magnetic resonance system 1 may need to be considered, which can be calculated using account models comprising a frequency characteristic.

Modelings using account models with frequency characteristics are characterized in that the loading of components by gradient pulse shapes GF requires an explicit consideration of spectra assigned to the gradient pulse shape GF.

Gradient coils and the basic field magnet are examples of hardware components that are typically modeled with a frequency characteristic. In both cases there can be frequency bands in which interactions due to the switching of the gradient currents can lead to unwanted mechanical or electrical resonances. It is important to limit the energy input in these frequency bands in order to avoid damaging the components.

The assignment of the possible parameter values PWij to the at least one category K1, K2, K3 may therefore additionally or alternatively comprise a calculation of a frequency-dependent loading.

For this purpose, the limit values Lim may comprise frequency bands that are to be avoided and the loaded characteristics may include at least one comparison value which specifies a maximum permitted energy content in a frequency band that is to be avoided.

A determination of such a comparison value may comprise a determination of an energy spectrum of the non-trapezoidal gradient pulse shape GF. This can be accomplished for example, by means of a normalized Fourier transform.

For example, an energy spectrum E (f) of a gradient having the gradient pulse shape GF G(t)=G f_{x/y/z}(t) can be determined during a measurement preparation by way of a (suitably normalized) Fourier transform FT such that the following applies:

$${E}_{x / y / z} ( f ) = {G}^{2} FT ( {f}_{x / y / z} ( t ) ) F T ( {f}_{x / y / z} ( t ) ) .$$

If the resonance bands that are to be avoided are known, the energy content within each resonance band 1 that is to be avoided (i.e. in a range of frequencies from f_{min,1} to f_{max,1}) can now be calculated. For this purpose, in the simplest case, the energy within a band can be integrated such that the following result is yielded for an energy content of a resonance band 1 that is to be avoided:

$${E}_{x / y / z , 1} = {}_{fmin , 1} {\int }^{fmax , 1} dt {E}_{x / y / z} ( f ) .$$

This value must for example not be greater than a permitted maximum value for the energy content of a resonance band Eₘₐₓ that is to be avoided, which may likewise be dependent on the respective axis x, y, z and/or on the frequency band 1.

It should be noted in this case that the gradient amplitude G is not yet known during the measurement preparation. In the measurement preparation, a maximum permitted gradient amplitude Gₘₐₓ is therefore determined which can be included and loaded as a comparison value in the characteristics CGF of the gradient pulse shape GF. Such a maximum permitted gradient amplitude Gₘₐₓ can be determined, for example according to the condition

$${G}_{max fmin , 1}^{2} {\int }^{fmax , 1} df FT ( {f}_{x / y / z} ( t ) ) FT ( {f}_{x / y / z} y ( t ) ) \leq {E}_{max} .$$

This value Gₘₐₓ can be used as a comparison value during the measurement planning in order to allocate an assignment of parameter values PWij, in particular value ranges of parameter values PWij, of measurement parameters mpj (in particular of the b-values) as appropriate to a category K1, K2, K3 and to mark them as appropriate. In this case, b-values which require higher gradient amplitudes than Gₘₐₓ could be assigned for example, to a category of “non-settable” parameter values PWij. Thus, no complex and time-consuming frequency analyses are necessary during the measurement planning, which allows a quick and interactive operation.

It may be provided in this case to indicate to a user a restriction of the parameter values PWij present due to an assignment to a category K1, K2, K3 of “non-settable” parameter values PWij. This can be affected for example as a notification, in particular already at a time the gradient pulse shape GF is read in, or as a “tooltip” during the measurement planning. The user can take this as a reason to adjust or not to choose affected non-trapezoidal gradient pulse shapes.

In the event that the gradient pulse shape GF is present on a fixed time grid, an associated energy spectrum can be determined by means of a discrete Fourier transform DFT or a fast Fourier transform (FFT), which likewise operate on a grid, and consequently possibly be determined faster. In this case the integrals are simplified to summations.

The determination of an energy spectrum of a gradient pulse shape GF can be used in order to determine the cutoff frequency F for account models with a time characteristic (cf. above). It is possible in this case for example to proceed according to the following equation:

$${}_{F} {\int }^{∞} df {E}_{x / y / z} ( f ) \leq {p}_{0} {\int }^{∞} df {E}_{x / y / z} ( f ) ,$$

where p denotes the fraction of an energy permitted above the cutoff frequency F and can amount for example to 20% or less, for example, 10%.

If axis-specific maximum values E_{max,x/y/z} for the energy content of at least one resonance band that is to be avoided are specified as limit values lim, axis-specific maximum gradient amplitudes G_{max,x/y/z} can also be used in the measurement planning.

Alternatively, from the different maximum gradient amplitudes G_{max,x/y/z} of the axes x, y, z, that maximum gradient amplitude Gₘₐₓ having the smallest value, i.e.

$${G}_{max} = min ( {G}_{max , k} ) ( k ∈ \{ x , y , z \} )$$

can be used as the maximum gradient amplitude Gₘₐₓ. In this way measurement protocols MP remain executable irrespective of rotation assignments.

A maximum permitted energy content and a corresponding comparison value can accordingly also be determined as a function of a respective axis x, y, z of the gradient unit 5 of the magnetic resonance system 1, and therefore axis-specifically, and the loaded characteristics CGF can then comprise at least the lowest of the comparison values determined for the different axes x, y, z of the gradient unit 5.

If more than one frequency band is to be avoided, a maximum permitted energy content and a corresponding comparison value can be determined for each of the frequency bands 1 that are to be avoided. Furthermore, the loaded characteristics CGF can comprise at least the lowest of the comparison values determined for the different frequency bands that are to be avoided such that Gₘₐₓ=min(G_{max,1}) applies.

In this case a determination of an energy content in a frequency band to be avoided may comprise a weighting, for example according to a resonance curve. For example, instead of an unweighted summation or integral formation of the energy within a resonance band to be avoided, a weighting can be estimated by means of which the resonance curve can be described. In a simple example, the weighting can take the form of a Gaussian curve that is symmetrical to the center of the resonance band to be avoided in which half the maximum value is reached precisely at the edges of the resonance band to be avoided.

Such a calculation of a frequency-dependent loading can comprise a scaling of amplitudes of the gradient pulse shape according to a characteristic frequency, for example the cutoff frequency F or a center frequency of the frequency band in which the highest energy is applied.

In this case a maximum permitted amplitude of a sinusoidal gradient pulse shape, the frequency of which lies in the center, in particular exactly on the center f_{M,1}=(f_{min,1}+f_{max,1})/2 of a resonance band 1 to be avoided which contains frequencies from f_{min,1} to f_{max,1}, can be calculated for example, as:

$${G}_{sin , 1} ( t ) = {G}_{max , 1} sin ( 2 π {f}_{M , 1} t + {φ}_{1} ) .$$

From this, E_{max,1} can be calculated according to

$${E}_{max , 1} = {}_{fmin , 1} {\int }^{fmax , 1} df {E}_{sin} ( f ) ,$$

with Eₛᵢₙ(f)=G²_{max,1}FT(sin(2πf_{M,1}t+Φ₁)) FT(sin(2πf_{M,1}t+φ_{i,1})), where the phase φ₁∈{−π, +π} can be chosen such that a minimum value results for E_{max,1}.

If the non-trapezoidal gradient pulse shape GF on axes Gx, Gy, Gz is defined in a logical coordinate system that does not correspond to the physical coordinate system of the axes x, y, z of the gradient unit 5, a determined energy spectrum can in turn be transferred by means of a suitable rotation matrix from the axes Gx, Gy, Gz into a suitable coordinate system.

With such rotations for transformation into a different, for example, physical, coordinate system and/or in the course of direction assignments, it should be noted that a determined energy spectrum can change in the axes into which the axes Gx, Gy, Gz are transformed as a result of the rotation. Analogously to the above-described formation of quadratic mean values, following a transformation by means of rotation matrix R, the following applies to the transformed normalized course f′ᵢ(t) of the gradient pulse shape GF:

$${f}_{i}^{′} ( t ) = {\sum }_{j} {R}_{i j} {f}_{j} ( t ) ,$$

and consequently on account of the linearity of the Fourier transform for an energy content E′ᵢ(f):

$$\begin{matrix}{E}_{i}^{′} ( f ) = {G}^{2} FT ( {f}_{i}^{′} ( t ) ) * FT ( {f}_{i}^{′} ( t ) ) \\ = {G}^{2} FT ( {\sum }_{j} {R}_{i j} {f}_{j} ( t ) ) FT ( {\sum }_{j} {R}_{i j} {f}_{j} ( t ) ) \\ = {G}^{2} {\sum }_{j} {R}_{i j} {\sum }_{1} {R}_{i 1} FT ( {f}_{j} ( t ) ) F T ( {f}_{1} ( t ) )\end{matrix}$$

Amplitude spectra Aᵢ(f)=FT(fᵢ(t)) can therefore be precalculated for each axis already in the course of the measurement preparation and energy spectra can be determined from this for any rotations on transformed, for example, physical, axes with little computational overhead and therefore quickly. If all the rotations are known already during the measurement preparation (for example when direction assignments are predefined), a maximum permitted gradient amplitude G_{max,m} can be determined already at this time for each rotation Rₘ. The smallest maximum gradient amplitude of this can for example be considered during the measurement planning: Gₘₐₓ=min{G_{max,m}.

For uniform non-trapezoidal gradient pulse shapes on all axes Gₙ(t)=G f(t) Vₙ, the direction vectors Vₙ=(v_{n,x}, v_{n,y}, v_{n,z}) have no effect on the shape of their spectra, but only on their amplitudes such that the following applies:

$${E}_{i , n} ( f ) = {G}^{2} {v}_{i , n}^{2} FT ( f ( t ) ) F T ( f ( t ) ) .$$

Thus, a maximum permitted gradient amplitude Gₘₐₓ can be determined easily and quickly for each direction vector Vₙ from a precalculated amplitude or energy spectrum A(t)=FT(f(t)) or E(t)=A²(t).

Depending on limit values lim applicable to a magnetic resonance system 1 and the associated modelings thereof by means of corresponding account models, different prepared characteristics can be applied which are skillfully used in order to enable rapid testing of the executability of measurement protocols MP. A common factor of all the methods is that precalculations in order to determine the characteristics of the at least one gradient pulse shape are performed (once) during the measurement preparation, and the results of these precalculations are used (repeatedly) during the measurement planning in order to enable an executable measurement protocol to be obtained.

A loading according to the disclosure of prepared characteristics CGF already described during a measurement preparation permits a swift calculation of loadings using account models with a frequency characteristic and consequently a rapid (possibly interactive) measurement planning. In this process, any gradient pulse shapes, without restrictions in terms of their design, can be chosen and executable parameter values PWij for measurement parameters mpj of a measurement protocol MP can quickly be determined. A determination of a maximum gradient amplitude Gₘₐₓ described here in this case assures in a simple manner an executability of a measurement using parameter values vPWij set according to the chosen assignment to the at least one category K1, K2, K3.

The method described can be performed without high demands in terms of computing power on a controller of the magnetic resonance system. This is accomplished by means of a combination of precalculations for determining the characteristics and/or approximations and analytical solutions in the calculation of loadings of the gradient unit 5.

Quick (and interactive) measurement planning is made possible as a result of the precalculations, wherein an executability of a measurement protocol MP is ensured while making allowance for different hardware components of the magnetic resonance system, and wherein different characteristics and modelings of loadings can be considered.

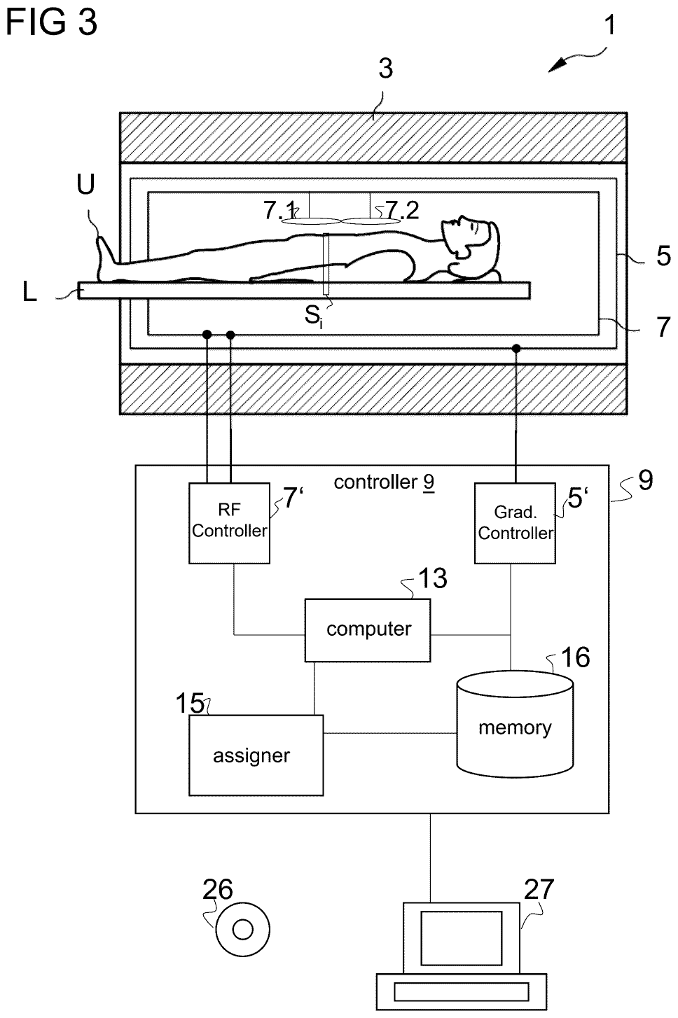

FIG. 3 schematically represents a magnetic resonance system 1 according to the disclosure. The system 1 may comprise a magnet unit 3 configured to generate the basic magnetic field, a gradient unit 5 configured to generate the gradient fields, a radiofrequency (RF) unit 7 configured to transmit and/or receive radiofrequency signals, and a controller 9 configured to control the system 1, which may include performing a method according to the disclosure.

These subunits of the magnetic resonance system 1 are illustrated only roughly schematically in FIG. 3. The radiofrequency unit 7 may consist of a plurality of subunits and for example comprise a plurality of coils. In particular, the radiofrequency unit 7 may comprise a bodycoil which is permanently integrated in the magnetic resonance system 1 and in turn may, for example comprise two antenna elements 7.1 and 7.2. The radiofrequency unit 7 may further comprise one or more different local coils 7* which can be configured either only for transmitting radiofrequency signals or only for receiving the triggered radiofrequency signals or for both and for their part may comprise a plurality of antenna elements and associated coil channels.

In order to examine an examination subject U, for example a patient or a phantom, the latter can be introduced on a couch L into the magnetic resonance system 1 in the measurement volume thereof. The slices S1 or S2 represent exemplary target volumes of the examination subject from which echo signals can be captured and acquired as measurement data.

The controller 9 may be configured to control the magnetic resonance system 1, including controlling the gradient unit 5 using a gradient controller 5′ and the radiofrequency unit 7 using a radiofrequency transmit/receive controller 7′. The radiofrequency unit 7 may comprise a plurality of channels on which signals can be sent or received. The controller 9 may include processing circuitry configured to perform one or more functions and/or operations of the controller 9. Additionally, or alternatively, one or more components (e.g., gradient controller 5′, RF transceiver controller 7′, computer 13, assigner 15, memory 16) of the controller 9 may include processing circuitry that is configured to perform one or more respective functions of the component(s).

The radiofrequency unit 7, together with its radiofrequency transmit/receive controller 7′, is responsible for generating and radiating (transmitting) an alternating radiofrequency field for manipulating the spins in a region that is to be manipulated (for example in slices S to be measured) of the examination subject U. In this case the center frequency of the alternating radiofrequency field, also referred to as the B1 field, is usually set as far as possible such that it lies close to the resonance frequency of the spins that are to be manipulated. Deviations of the center frequency from the resonance frequency are referred to as off-resonance. In order to generate the B1 field, currents controlled by means of the radiofrequency transmit/receive controller 7′ are applied to the RF coils in the radiofrequency unit 7.

The controller (control device) 9 may further comprise an assignment unit (assigner) 15 for the assignment of parameter values to categories according to the disclosure. The controller 9 is designed overall for performing a method according to the disclosure.

A computing unit (computer, processor, processing circuitry) 13 incorporated into the controller 9 may be configured to perform computational operations necessary for the requisite measurements and provisions. Interim results and results required for this or determined in the process can be stored in a memory unit 16 of the controller 9. The units illustrated are in this case not necessarily to be understood as physically separate units, but simply represent a subdivision into notional units which, however, can also be implemented for example, in a fewer number or even in just one single physical unit.

Control commands can be conducted, for example, by a user, to the magnetic resonance system via an input/output device (input/output interface, computer) 27 of the magnetic resonance system 1 and/or results of the controller 9, such as for example, image data, can be displayed.

A method described herein may also be present in the form of a computer program comprising commands which perform the described method on a controller 9. A computer-readable storage medium 26 may also be present, comprising commands which, when executed by a controller 9 of a magnetic resonance system 1, cause the controller 9 to perform the described method.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for acquiring diffusion-weighted measurement data of an examination subject by a magnetic resonance system using a measurement protocol containing non-trapezoidal gradient pulse shapes for the diffusion encoding, the method comprising:
loading prepared characteristics for at least one non-trapezoidal gradient pulse shape of the measurement protocol;
loading limit values that a hardware unit of the magnetic resonance system is not to exceed;
assigning, based on the loaded prepared characteristics while complying with the loaded limit values, parameter values of at least one measurement parameter to be set in the measurement protocol to at least one category indicating an executability of the measurement protocol on the magnetic resonance system;
inputting, based on one or more of the assigned parameter values, at least one desired parameter value of at least one measurement parameter of the measurement protocol;
based on a parameter value in which the measurement protocol is executable not having yet been input for each measurement parameter to be set in the measurement protocol, repeating the assigning of the parameter values and the inputting of the at least desired parameter value, at least for measurement parameters for which no parameter value has yet been set and until parameter values for which the measurement protocol is executable have been input for all the measurement parameters of the measurement protocol that are to be set, to determine the measurement protocol containing the input parameter values; and
acquiring diffusion-weighted measurement data based on the determined measurement protocol containing the input parameter values.

2. The method as claimed in claim 1, wherein the at least one non-trapezoidal gradient pulse shape is defined along at least one axis that extends in a direction of a coordinate system, and wherein the at least one non-trapezoidal gradient pulse shape is defined based on a predetermined scaling factor assigned to the direction of a logical coordinate system.

3. The method as claimed in claim 1, wherein the assignment of the parameter values to the at least one category comprises: calculating at least one loading on at least one axis in a coordinate system, the calculation of the loading including transforming from the coordinate system of the gradient pulse shape into a coordinate system of the magnetic resonance system.

4. The method as claimed in claim 1, wherein the loaded prepared characteristics comprise characteristic subsections of the gradient pulse shape.

5. The method as claimed in claim 4, wherein:
characteristic subsections are determined based on a characteristic time period,
a determination of the characteristic time period comprises conducting a frequency analysis of the gradient pulse shape and determining a cutoff frequency of the gradient pulse shape, and
the cutoff frequency is determined such that a predetermined percentage of a pulse energy applied by the gradient pulse shape is applied in a frequency band above the cutoff frequency.

6. The method as claimed in claim 4, wherein a gradient pulse shape is subdivided into subareas, and for each subarea, a characteristic time period is determined which subdivides the respective subarea of the gradient pulse shape into a minimum number of characteristic subsections.

7. The method as claimed in claim 4, wherein for each characteristic subsection, the method further comprises determining a constant amplitude corresponding to a loading caused by the gradient pulse shape in a respective subsection.

8. The method as claimed in claim 7, wherein the determining the constant amplitude comprises:
forming a mean value of an amplitude of the gradient pulse shape in the subsection;
forming a weighted mean value of the amplitude of the gradient pulse shape in the subsection; or
determining a maximum value of the amplitude of the gradient pulse shape in the subsection.

9. The method as claimed in claim 4, wherein the assignment of the parameter values to the at least one category comprises: performing a section-by-section calculation based on the subsections of a loading according to a corresponding account model for ohmic losses and/or for a power supply.

10. The method as claimed in claim 1, wherein the loaded characteristics comprise a normalized guidance value for an amplitude of the gradient pulse shape over its entire course, and wherein the assignment of the parameter values to the at least one category comprises a calculation of a loading according to a corresponding account model using a desired diffusion weighting by the gradient pulse shape.

11. The method as claimed in claim 10, further comprising determining normalized guidance values for an amplitude of the gradient pulse shape of desired parameter values for a planned set of different b-values and/or diffusion directions; and loading an averaged normalized guidance value for an amplitude of the gradient pulse shape for the set of different b-values and/or diffusion directions, wherein the assignment of the parameter values to the at least one category is based on the averaged normalized guidance value.

12. The method as claimed in claim 1, wherein the limit values comprise avoided frequency bands, and the loaded characteristics comprise at least one comparison value specifying a maximum permitted energy content in a frequency band of the avoided frequency bands.

13. The method as claimed in claim 12, wherein the assignment of the parameter values to the at least one category comprises: calculating a frequency-dependent loading, and wherein the calculation of the frequency-dependent loading comprises scaling amplitudes of the gradient pulse shape based on a characteristic frequency of the frequency band in which a highest energy is applied.

14. The method as claimed in claim 12, wherein:
determining the comparison value comprises determining an energy spectrum of the non-trapezoidal gradient pulse shape, and/or
a maximum permitted energy content and a corresponding comparison value are determined as a function of a respective axis of the gradient unit of the magnetic resonance system, and the loaded characteristics comprise at least a lowest of the comparison values determined for the different axes of a gradient unit.

15. One or more non-transitory media storing instructions that, when executed by one or more processors, cause the one or more processors to perform the method of claim 1.

16. An apparatus comprising: one or more processors; and memory storing instructions that, when executed by the one or more processors, cause the apparatus to perform the method of claim 1.

17. A magnetic resonance (MR) system comprising:
a scanner; and
a controller configured to:
load prepared characteristics for at least one non-trapezoidal gradient pulse shape of a measurement protocol;
load limit values that a hardware unit of the magnetic resonance system is not to exceed;
assign, based on the loaded prepared characteristics while complying with the loaded limit values, parameter values of at least one measurement parameter to be set in the measurement protocol to at least one category indicating an executability of the measurement protocol on the magnetic resonance system;
input, based on one or more of the assigned parameter values, at least one desired parameter value of at least one measurement parameter of the measurement protocol;
based on a parameter value in which the measurement protocol is executable not having yet been input for each measurement parameter to be set in the measurement protocol, repeating the assigning of the parameter values and the inputting of the at least desired parameter value, at least for measurement parameters for which no parameter value has yet been set and until parameter values by means of which the measurement protocol is executable have been input for all the measurement parameters of the measurement protocol that are to be set, to determine the measurement protocol containing the input parameter values; and
control the scanner to acquire diffusion-weighted measurement data based on the determined measurement protocol containing the input parameter values.

18. The MR system of claim 17, wherein the scanner comprises a magnet unit, a gradient unit, and a radio-frequency unit; and the controller comprises a radio-frequency transmit-receive controller and an assignment unit.
